(19) United States
(12) Patent Application Publication
(10) Pub. No.: US 2026/0371460 A1
(43) Pub. Date: Nov. 19, 2026

(54) HALF BRIDGE SWITCH NODE SHIELDED FROM INPUT VOLTAGE AND GROUND

(71) Applicant: SIGNIFY HOLDING B.V., EINDHOVEN (NL)

(72) Inventor: BERND ACKERMANN, AACHEN (DE)

(21) Appl. No.: 19/103,325

(22) PCT Filed: Aug. 7, 2023
(86) PCT No.: PCT/EP2023/071777

§ 371 Date: Feb. 12, 2025

(30) Foreign Application Priority Data
Aug. 15, 2022 (EP) 22190377.6
Sep. 13, 2022 (EP) 22195443.1

(51) Int. Cl. H05B 45/3725; H02M 3/00; H10W 42/20

(52) U.S. Cl. CPC H05B 45/3725; H02M 3/003; H10W 42/261

(57) ABSTRACT

The invention relates to a semiconductor device comprising a semiconductor switching element, a semiconductor device package for encapsulating the semiconductor switching element, a first electrode for providing a first voltage to the semiconductor switching element, a second electrode for providing a second voltage to the semiconductor switching element, wherein the first voltage is larger than the second voltage when the semiconductor switching element is open, wherein the first electrode and the second electrode are mounted on one side of the semiconductor device package and are adapted to be soldered to a printed circuit board, wherein the semiconductor device further comprises a first shield electrode, wherein the shield electrode is placed between the first electrode and the second electrode, and wherein the shield electrode is coupled to a third voltage that is smaller than the first voltage and larger than the second voltage and placed such that a creepage distance between the first electrode and the second electrode is increased.

### FIELD OF THE INVENTION

The invention relates to a semiconductor device. The invention further relates to a printed circuit board. The invention further relates to a driver. The invention further relates to a luminaire.

### BACKGROUND OF THE INVENTION

Safe operation of light emitting diode, LED, drivers and other switched-mode power supplies, SMPSs, requires obeying the creepage and clearance distances and distances through insulation, which are defined e.g. in IEC 60664 insulation coordination for equipment within low-voltage systems. Fully exploiting the benefits of wide bandgap (WBG) semiconductors-Silicon Carbide, SiC, and Gallium Nitride, GaN, in an SMPS results in peak working voltages and switching frequencies that are substantially larger than those of a state-of-the-art SMPS using Silicon, Si, semiconductors.

A predefined physical distance between a first electrode and a second electrode is required to accommodate a safe operation by meeting the requirements of the creepage and clearance. If the semiconductor switching element inside the semiconductor device is open, the first voltage will be present across a semiconductor device, i.e. between the first electrode and the second electrode. If the requirements of creepage and clearance are not met, e.g. the creepage distance provided between the first electrode and the second electrode is smaller than required for a specific voltage, a voltage breakdown may occur between the first electrode and the second electrode. This breakdown occurs at the surface of the semiconductor switching element. The breakdown may cause undesired operation of the circuit but also a risk of fire may occur. The requirements of creepage and clearance are mainly determined by the amplitude of the voltage and the frequency of the voltage. An increase in voltage or frequency will result in an increase in the required creepage and clearance distances. FIG. 1 shows the maximum bound of maintaining 20 mm creepage in relation to the voltage amplitude and the frequency. With new solid state devices such as Gallium Nitride, GaN, and Silicon Carbide, SiC, semiconductors, the switching frequency of the semiconductor switching element can be increased significantly. This may be beneficial when used in switched mode power supplies since this allows a further miniaturisation of the switched mode power supply, SMPS. FIG. 1 shows that in order to maintain the 20 mm creepage distance, the voltage has to be lowered drastically in order to operate at higher frequencies. For a SMPS to operate at both high frequencies and high voltages, the creepage distance needs to be increased significantly. Operating at a voltage of 500 V at 1.5 MHz may result in a creepage distance of 10 mm. As can already be seen, such large creepage distances prevent any form of miniaturisation.

### SUMMARY OF THE INVENTION

It is an objective of the invention to provide a semiconductor device that does not, or less, suffer from the creepage requirements when operated at a relatively high voltage at a high operating frequency.

To overcome this concern, in a first aspect of the invention a semiconductor device is provided. The semiconductor device comprises:
a semiconductor switching element;
a semiconductor device package for encapsulating the semiconductor switching element;
a first electrode for providing a first voltage to the semiconductor switching element;
a second electrode for providing a second voltage to the semiconductor switching element, wherein the first voltage is larger than the second voltage when the semiconductor switching element is open;
wherein the first electrode and the second electrode are mounted on one side of the semiconductor device package and are adapted to be soldered to a printed circuit board,
wherein the semiconductor device further comprises a first shield electrode, wherein the shield electrode is placed between the first electrode and the second electrode, and wherein the shield electrode is coupled to a third voltage that is smaller than the first voltage and larger than the second voltage and placed such that a creepage distance between the first electrode and the second electrode is increased.

A semiconductor switching element is preferably integrated as an integrated circuit, IC. The semiconductor switching element is encapsulated in a package that allows to be mounted on a printed circuit board, PCB. The semiconductor switching element is capable of closing and opening, thereby creating or blocking an electric conducting path respectively between the first electrode and the second electrode. The semiconductor device may be coupled to a first voltage that can be connected or disconnected to other electronic components using the semiconductor device. A first electrode may be coupled to the first voltage and the second electrode may be connected to the other electronic components or a second voltage. The semiconductor device according to the claims also has at least a first shield electrode. This shield electrode is coupled to a third voltage that has an amplitude that lies between the first voltage and the second voltage. Additionally, the shield electrode is placed between the first electrode and the second electrode. It is an insight of the inventor that the creepage distance increases exponentially with the voltage amplitude at high frequencies. A reduction in voltage therefore exponentially reduces the creepage distance that is required. By placing a shield electrode between the first electrode and the second electrode and having the shield electrode connected to a voltage between the first voltage and the second voltage, two voltage differences are created. Firstly, a voltage is present between the first electrode and the shield electrode. Secondly, a voltage is present between the shield electrode and the second electrode. Both of these voltages are lower than the voltage between the first electrode and the second electrode. The sum of the two voltages may however be equal to the voltage between the first electrode and the second electrode. Because of the exponential reduction of the creepage distance, the total creepage distance has been reduced. As an example, the voltage between the first electrode and the second electrode may be 500 V and have a frequency of 1.5 MHz, the semiconductor switching element is switching at a frequency of 1.5 MHz. the first voltage may then be 500 V and the second voltage may then be 0 V. The shield electrode is placed exactly halfway between the first electrode and the second electrode and connected to a voltage of 250 V. The creepage between the first electrode and the shield electrode should be the same as the creepage between the shield electrode and the second electrode. In this example, the creepage for a voltage of 250 V at 1.5 MHz is about 0.5 mm.

Since the total sum of creepage distances is now reduced, the semiconductor device can be made smaller while operating at a higher voltage and frequency.

In a further example, the shield electrode is further arranged to provide an electric conductive path from one end of the semiconductor device package to another opposing end of the semiconductor device package.

To further improve the creepage distance, the shield electrode provides an electric conductive path from one end of the semiconductor device package to another opposing end of the semiconductor device package. This provides a safe way of realising the required creepage distances because the first voltage cannot bypass the shield electrode anymore.

In a further example, the shield electrode is placed closer to the second electrode than to the first electrode.

The closer the shield electrode is placed to the second electrode, the lower the third voltage may be, allowing a lower voltage to be generated as third voltage, which may simplify a voltage source that provides the third voltage.

In a further example, the shield electrode is placed at halfway between the first electrode and the second electrode.

Placing the shield electrode is placed at halfway between the first electrode and the second electrode provides a symmetrical voltage distribution. The voltage across the first electrode and the shield electrode may be the same as the voltage across the shield electrode and the second electrode.

In a further example, the third voltage is half the voltage of the first voltage.

Preferably, also in combination with the placement of the shield electrode being placed at halfway between the first electrode and the second electrode, the voltage may be evenly distributed.

In a further example, the semiconductor device comprises any of a Gallium Nitride, GaN, or Silicon Carbide, SiC, semiconductor material.

Using GaN or SiC semiconductor material allows higher frequency operations, causing even stricter creepage requirements.

In a further example, the semiconductor switching element is a diode.

The diode may only have a first electrode and a second electrode. No other electrodes are needed. The shield electrode can easily be placed between the first electrode and the second electrode.

In a further example, the semiconductor switching element further comprises a control electrode for providing a control signal for controlling the semiconductor switching element, wherein the semiconductor switching element is a transistor.

Alternatively to the diode, the semiconductor switching element may be a transistor. GaN and SiC may be used for diodes and for transistors such as Metal Oxide Silicon Field Effect Transistor, MOSFET.

In a further example, a printed circuit board, PCB, is provided. The PCB comprises:
a first trace adapted to be provided with the first voltage and coupled to the first electrode;
a second trace adapted to be provided with the second voltage and coupled to the second electrode;
the semiconductor device according to any of the preceding examples.

Any PCB whereupon the semiconductor device is mounted may also improve the creepage performance. The first voltage is provided via a first trace to the first electrode. The second voltage is provided via the second trace to the second electrode.

In a further example, a third trace is adapted to be provided with the third voltage and is coupled to the shield electrode, wherein the shield electrode is placed physically between the first trace and the second trace.

Additionally, a third trace may be used to provide the third voltage to the shield electrode. If difference between the second voltage and the third voltage is relatively small compared to the difference between the first voltage and the third voltage, the third trace may be placed close to the second trace, allowing an easier layout of traces on the PCB.

Preferably, traces going to and from the semiconductor device are placed in an inner layer of the PCB. In the inner layer, there is no creepage and therefore no creepage requirements. Vias under the semiconductor device can be directly electrically coupled to the electrodes of the semiconductor device. This minimizes the problems with creepage at PCB level. Optionally, a coating may be provided on the top layer of the PCB to reduce or get rid of creepage problems at all. Such a layer may for example be an acrylic, silicone, or urethane resin.

In a further example a driver for driving a light emitting diode, LED, lighting load is provided. The driver comprises:
the PCB;
electric components mounted on the PCB as to form a switched mode power supply using the semiconductor switching element as a main power conversion switch.

Preferably, the invention is implemented in a driver for driving an LED lighting load. The driver is preferably very small because e.g. in retrofit applications, the driver needs to be integrated in a retrofittable housing such as an Edison screw bulb. A small driver is also preferred in other applications, such as integration of a driver in or with a rail system.

In a further example, the driver is formed as any of a buck converter, a boost converter, a buck-boost converter, an LLC converter or a flyback converter.

Preferably, the driver is any of a buck converter, a boost converter, a buck-boost converter, an LLC converter or a flyback converter.

In a further example, the driver comprises a second semiconductor device, wherein the semiconductor device and the second semiconductor device are arranged to operate the switched mode power supply as a synchronous switched mode power supply.

Providing a second semiconductor device according to the invention allows the driver to operate at an even further increased miniaturisation. An SMPS often uses two semiconductor devices for operating and transferring regulated power to the load. If both are semiconductor devices according to the invention, the driver is optimized. If both the semiconductor devices are transistors, the driver may operate as a synchronous converter.

In a further example, the driver may comprise a second semiconductor device, wherein the semiconductor device and the second semiconductor device are arranged to operate as a half bridge.

Instead of operating as a synchronous converter, the driver may also use a half bridge topology. E.g., a resonant converter uses a half bridge with two semiconductor devices coupled in series. The node between the two semiconductor devices is coupled to a resonant tank. Another benefit can be derived from this topology. The node between the two semiconductor devices can be used to derive the third voltage.

In another example, a luminaire is provided. The luminaire comprises the driver and the LED lighting load.

### BRIEF DESCRIPTION OF THE DRAWINGS

Examples of the invention will now be described with reference to the accompanying drawings, in which:

FIG. 1 shows an example of a graph showing a relation between voltage amplitude and frequency using 20 mm creepage.

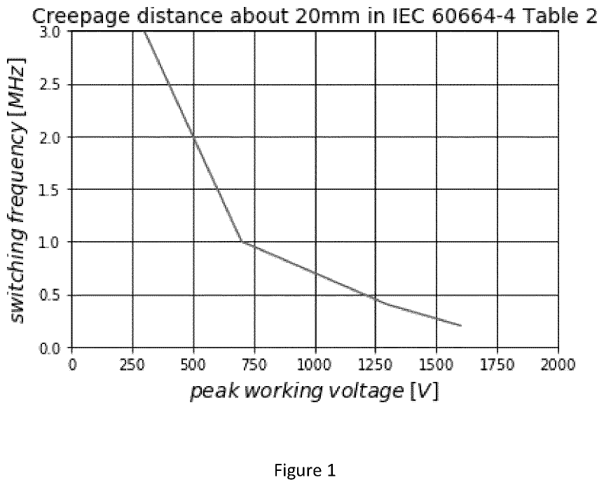

FIG. 2 shows an embodiment of a semiconductor device.

FIG. 3 shows a further embodiment of a semiconductor device.

FIG. 4 shows an embodiment of a semiconductor device in the form of a diode.

FIG. 5 shows an embodiment of an application of the semiconductor device in an electronic circuit.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should also be understood that the Figures are merely schematic and are not drawn to scale. It should also be understood that the same reference numerals are used throughout the Figures to indicate the same or similar parts.

The invention relates to a semiconductor device 5 that comprises a semiconductor switching element M1, a semiconductor device package for encapsulating the semiconductor switching element M1, a first electrode for providing a first voltage to the semiconductor switching element M1, a second electrode for providing a second voltage to the semiconductor switching element M1, wherein the first voltage is larger than the second voltage when the semiconductor switching element M1 is open.

The first electrode and the second electrode are mounted on one side of the semiconductor device package and are adapted to be soldered to a printed circuit board. The semiconductor device 5 further comprises a first shield electrode, wherein the shield electrode is placed between the first electrode and the second electrode, and wherein the shield electrode is coupled to a third voltage that is smaller than the first voltage and larger than the second voltage and placed such that a creepage distance between the first electrode and the second electrode is increased.

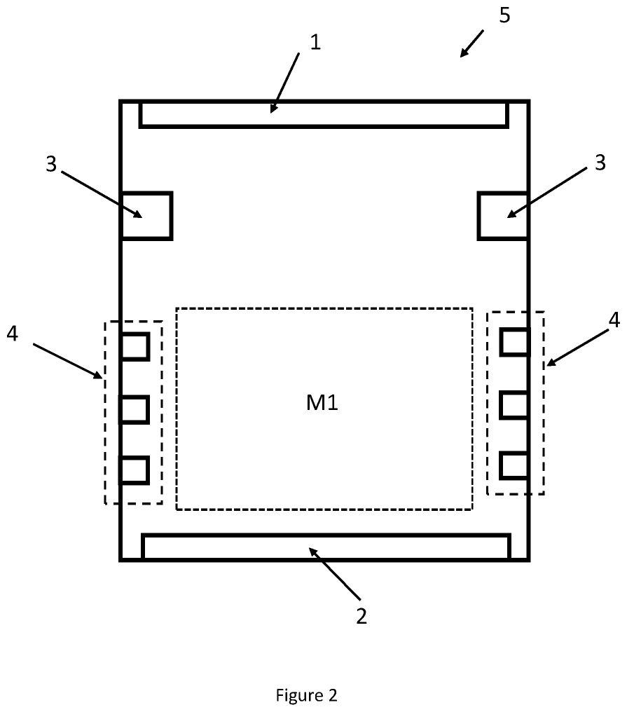

FIG. 2 shows an example of a semiconductor device 5. The semiconductor device 5 is an IC that has semiconductor circuitry integrated in the package. The semiconductor device 5 has a semiconductor switching element M1. In this example, the semiconductor switching element M1 is shown as a transistor, e.g. a MOSFET. The semiconductor device 5 may have additional circuitry integrated to control the semiconductor switching element M1, such as a gate driver. The gate driver may be powered and receive control signals via electrodes 4. Alternatively, only a semiconductor switching element M1 is provided in the package and the semiconductor switching element M1 receives a control signal via the electrode 4. An external gate drive may then be used to provide a gate drive signal. The semiconductor switching element M1, and optionally additional electronics are encapsulated in the semiconductor device package to form an IC. A first electrode 1 is provided for the semiconductor device 5. The first electrode 1 may be used for soldering to a first trace at a PCB. In the example of a transistor or MOSFET as a semiconductor switching element M1, the first electrode 1 may be connected to the collector or drain of the semiconductor switching element M1. A second electrode 2 is provided for the semiconductor device 5. The second electrode 2 may be used for soldering to a second trace at the PCB. In the example of a transistor or MOSFET as a semiconductor switching element M1, the second electrode 2 may be connected to the emitter or source of the semiconductor switching element M1. preferably, all electrodes are mounted on one side of the semiconductor device package. FIG. 2 shows all electrodes mounted on the bottom side of the semiconductor device package. Alternatively, all electrodes can be mounted on the circumferential side of the semiconductor device package. The semiconductor device 5 further has at least one shield electrode 3 that is preferably placed on the same side of the semiconductor device package as the first electrode 1 and the second electrode 2. The shield electrode 3 is placed between the first electrode 1 and the second electrode 2. The shield electrode 3 is preferably coupled to a third trace on the PCB. The first electrode 1 is coupled to a first voltage. The second electrode 2 is coupled to a second voltage, which is smaller than the first voltage. The shield electrode 3 is coupled to a third voltage that is smaller than the first voltage and higher than the second voltage.

FIG. 2 shows that a first shield electrode 3 is provided at one end of the semiconductor device package and a second shield electrode 3 is provided at an opposite end of the semiconductor device package. In this example, it is assumed that the creepage distance between the first electrode 1 and the second electrode 2 at the semiconductor device package is considered to meet the requirements and is therefore acceptable. The creepage distance via the PCB may however be more complicated. It may therefore be that the creepage between the first electrode 1 and the second electrode 2 at the semiconductor device package is good, while the creepage between the first electrode 1 and the second electrode 2 at the PCB is not good. The first electrode 3 and the second electrode 3 placed at the edges of the semiconductor device package increase the creepage distance between the first electrode 1 and the second electrode 2 via the PCB. Depending on the lay-out of the electrodes, a single shield electrode 3 may be sufficient e.g. the first electrode 1 is placed more to the left or right of the semiconductor device package

In order to also improve the creepage distance at the semiconductor device package, the shield electrode 3 may be placed such that a direct creepage path between the first electrode 1 and the second electrode 2 is interrupted. The shield electrode 3 effectively stands in the creepage path, causing the creepage path to go besides the shield electrode 3, effectively increasing the creepage between the first electrode 1 and the second electrode 2. The introduction of the shield electrode 3 in the creepage path provides two additional creepage requirements, the creepage between the first electrode 1 and the shield electrode 3 and the creepage between the shield electrode 3 and the second electrode 2. The shield electrode 3 is coupled to a voltage that lies between the first voltage and the second voltage. Therefore, the voltage between the first electrode 1 and the shield electrode 3 and the voltage between the shield electrode 3 and the second electrode 2 is lower than the voltage between the first electrode 1 and the second electrode. This means that between the first electrode 1 and the shield electrode 3 and the shield electrode 3 and the second electrode 2, lower creepage distances are needed. As an example, the first voltage may be 480 V. The semiconductor switching element M1 may switch at a frequency of 1 Mhz. The second voltage may be 0 V. With a voltage of 500 V with a frequency of 1.5 MHz, a creepage distance of 10 mm is needed between the first electrode 1 and the second electrode 2. When the third voltage is 250 V at a steady level, the creepage between the first electrode and the second electrode needs to be about 0.5 mm and the creepage between the shield electrode 3 and the second electrode needs to be about 0.5 mm. The sum of the required creepage distances between the first electrode 1 and the shield electrode 3 and the shield electrode 3 and the second electrode 2 is smaller than the required creepage distance between first electrode 1 and the second electrode 2. The shield electrode 3 can be dimensioned such that it extends the creepage distance between the first electrode 1 and the second electrode 2.

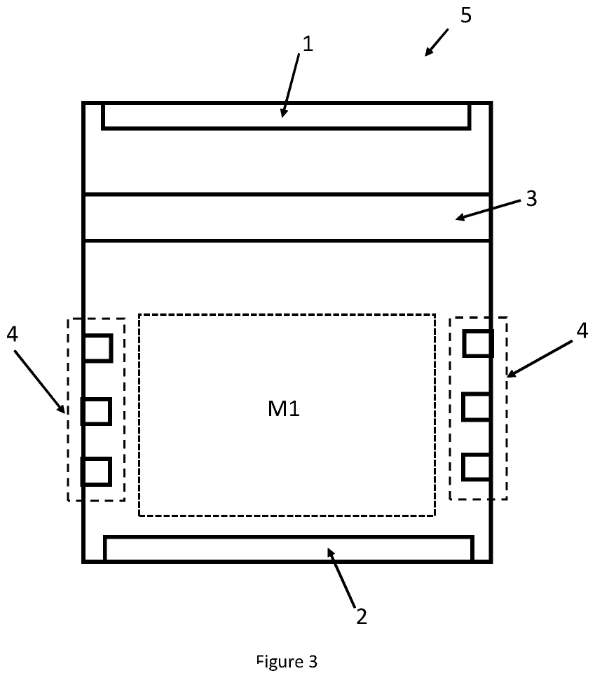

FIG. 3 shows another example of a semiconductor device 5. In this example, a transistor is used as a semiconductor switching element M1. The semiconductor device 5 may be built up similar as the semiconductor device 5 as shown in FIG. 2. The semiconductor device 5 improves the creepage distance over the semiconductor device package. The shield electrode 3 extends from one end of the semiconductor device package to an opposite or other end of the semiconductor device package. The shield electrode is not only in the path of the creepage between the first electrode 1 and the second electrode 2 but it effectively blocks any path on the side of the semiconductor device package where the electrodes are present. Therefore, the creepage distance is even more improved. In this example, the creepage distance will be most likely more critical on the PCB since the creepage requirements on the semiconductor device package are improved significantly.

For the examples relating to the semiconductor switching element M1 as a transistor, the creepage distance has been identified as a distance between the first electrode 1 and the second electrode 2. Other creepage distances may as well be relevant where a shield electrode 3 may provide an improvement on the creepage. An example would be the creepage distance between the first electrode 1 and the electrode 4. The voltage of the electrode 4 will not differ significantly from the voltage of the first electrode 1.

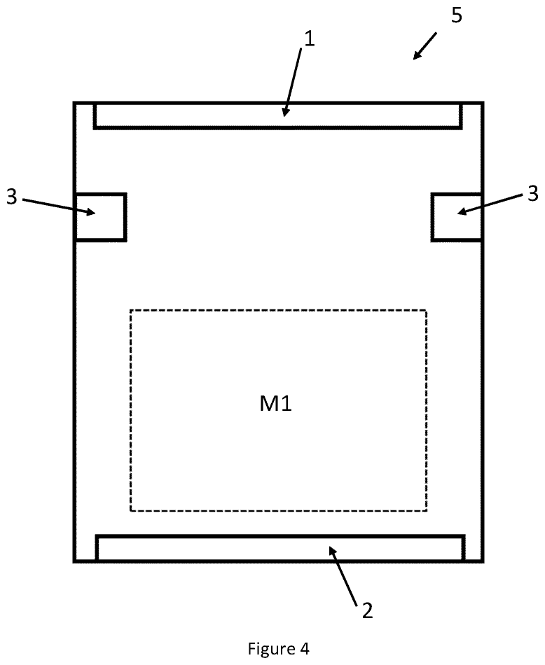

FIG. 4 shows an example of a semiconductor device 5 with a semiconductor switching element M1 that may be a diode. The diode has only two pins, an anode and a cathode. The anode may be coupled to the first electrode 1 and the cathode may be coupled to the second electrode 2. Similar as with the examples where the semiconductor switching element M1 is a transistor, a shield electrode 3 is provided between the first electrode 1 and the second electrode 2. In the example provided in FIG. 4, a first shield electrode 3 is provided at one end of the semiconductor device package and a second shield electrode 3 is provided at an opposite end of the semiconductor device package. In this example, it is assumed that the creepage distance between the first electrode 1 and the second electrode 2 at the semiconductor device package is considered to meet the requirements and is therefore acceptable. The creepage distance via the PCB may however be more complicated. It may therefore be that the creepage between the first electrode 1 and the second electrode 2 at the semiconductor device package is good, while the creepage between the first electrode 1 and the second electrode 2 at PCB is not good. The first electrode 3 and the second electrode 3 placed at the edges of the semiconductor device package increase the creepage distance between the first electrode 1 and the second electrode 2 via the PCB. Depending on the lay-out of the electrodes, a single shield electrode 3 may be sufficient e.g. the first electrode 1 is placed more to the left or right of the semiconductor device package.

In order to also improve the creepage distance at the semiconductor device package, the shield electrode 3 may be placed such that a direct creepage path between the first electrode 1 and the second electrode 2 is interrupted. The shield electrode 3 effectively stands in the creepage path, causing the creepage path to go besides the shield electrode 3, effectively increasing the creepage between the first electrode 1 and the second electrode 2. The introduction of the shield electrode 3 in the creepage path provides two additional creepage requirements, the creepage between the first electrode 1 and the shield electrode 3 and the creepage between the shield electrode 3 and the second electrode 2. The shield electrode 3 is coupled to a voltage that lies between the first voltage and the second voltage. Therefore, the voltage between the first electrode 1 and the shield electrode 3 and the voltage between the shield electrode 3 and the second electrode 2 is lower than the voltage between the first electrode 1 and the second electrode. This means that between the first electrode 1 and the shield electrode 3 and the shield electrode 3 and the second electrode 2, lower creepage distances are needed.

Similar as in FIG. 3, the semiconductor device 5 having a diode as a semiconductor switching element M1 may also be provided with a shield electrode 3 that extends from one end of the semiconductor device package to an opposite or other end of the semiconductor device package. The shield electrode is not only in the path of the creepage between the first electrode 1 and the second electrode 2 but it effectively blocks any path on the side of the semiconductor device package where the electrodes are present. Therefore, the creepage distance is even more improved. In this example, the creepage distance will be most likely more critical on the PCB since the creepage requirements on the semiconductor device package are improved significantly.

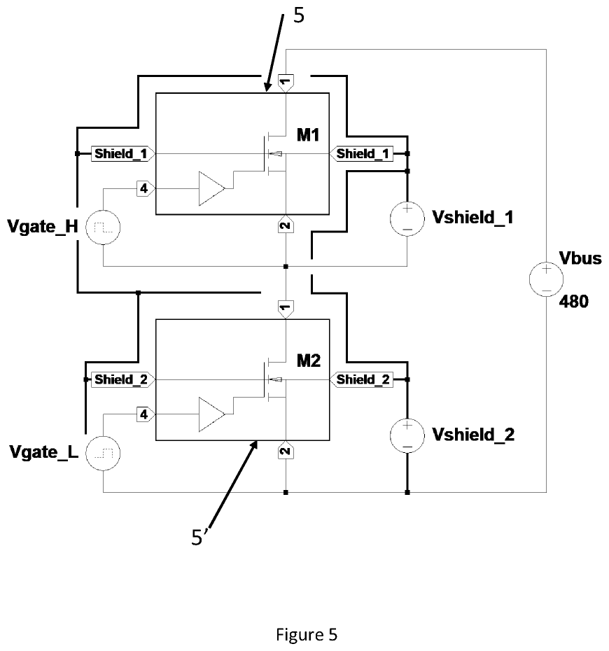

FIG. 5 shows an example of an implementation of the semiconductor device 5. Two semiconductor devices 5 are provided and are coupled in series. This connection may be used in several applications such as a half bridge configuration or in an SMPS where one semiconductor device 5 is provided with as a semiconductor switching element M1, M2 as a transistor and the other semiconductor device 5 is provided with as a semiconductor switching element M1,M2 as a diode. Alternatively, when the SMPS is configured as a synchronous converter, the other semiconductor device 5 is provided with as a semiconductor switching element M1, M2 as a transistor.

The shield electrodes Shield_1 and Shield_2 are the shield electrodes 3 of the corresponding semiconductor devices 5. In the example shown in FIG. 5, both semiconductor devices 5 have a transistor as semiconductor switching element M1, M2. Gate drive signal Vgate_H is provided to the first semiconductor device 5 and gate signal Vgate_L is provided to the second semiconductor device 5′. The gate signals may be amplified or modified in the semiconductor devices 5 before they provide a signal to the corresponding gates of the transistors. The semiconductor devices 5 are mounted on a PCB. The gate signals Vgate_L and Vgate_H are provided to the corresponding semiconductor devices 5 via traces on the PCB. A first voltage is provided to the first electrode 1 of the first semiconductor device 5 via a trace. The second electrode 2 of the first semiconductor device 5 is coupled to the first electrode 1 of the second semiconductor device 5′. The second electrode 2 of the second semiconductor device 5′ is coupled to a second voltage, that is also provided via a trace. All traces are provided on the same PCB. While routing these traces on the PCB, creepage distances have to be taken into consideration. Similar as for the semiconductor device 5, the creepage distance at the PCB may also become very larger when operating at high voltages with high frequencies. It is therefore also desired to continue the shield from the shield electrodes 3 onto the PCB. The shield electrode of the first semiconductor device 5 is coupled to a voltage Vshield_1. Preferably, the voltage Vshield_1 is provided by a voltage source. The voltage is preferably constant. Preferably, the voltage reference of the voltage Vshield_1 is coupled to the second electrode 2 of the first semiconductor device 5.

Preferably, the voltage Vshield_2 is provided by a voltage source. The voltage is preferably constant. Preferably, the voltage reference of the voltage Vshield_2 is coupled to the second electrode 2 of the second semiconductor device 5′. Preferably, the voltage of the second electrode 2 is low pass filtered to provide the voltage reference of the voltage Vshield_2. The shielding traces are placed strategically around the traces that carry the high voltage at high frequencies. The creepage requirements are for these traces then made simpler to comply with, i.e. the total creepage distance can be reduced.

The semiconductor devices 5 as provided in the examples may be implemented in a driver for driving a light emitting diode, LED, lighting load. The driver may comprise the PCB on which electronic circuitry is located including the semiconductor devices 5 and traces for coupling the circuitry together. The driver may be reduced in size when implementing the semiconductor devices 5. The reduction in size may be even more improved when the shield electrodes 3 are extended by shield traces. The driver may comprise any type of SMPS such as a buck converter, a boost converter, a buck-boost converter, an LLC converter or a flyback converter. The driver may operate as a synchronous SMPS.

The driver may be part of a luminaire. The luminaire may then comprise the driver and the LED lighting load. The luminaire may be very compact since the size of at least the driver can be reduced.

The electrodes provided in the examples may have any kind of shape. The electrodes can be shaped such that they fit optimally with the design that is required. The electrodes may also be used for cooling down the semiconductor device 5, i.e. they may serve as thermal pads. Depending on the number of signals that need to be provided to the semiconductor device, the number of electrodes may also vary.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A semiconductor device comprising:
a semiconductor switching element;
a semiconductor device package for encapsulating the semiconductor switching element;
a first electrode for providing a first voltage to the semiconductor switching element; and
a second electrode for providing a second voltage to the semiconductor switching element, wherein the first voltage is larger than the second voltage when the semiconductor switching element is open;
wherein the first electrode and the second electrode are mounted on one side of the semiconductor device package and are adapted to be soldered to a printed circuit board,
wherein the semiconductor device further comprises a first shield electrode, wherein the shield electrode is placed between the first electrode and the second electrode, and wherein the shield electrode is coupled to a third voltage that is smaller than the first voltage and larger than the second voltage and placed such that a creepage distance between the first electrode and the second electrode is increased.

2. The semiconductor device according to claim 1, wherein the shield electrode is further arranged to provide an electric conductive path from one end of the semiconductor device package to another opposing end of the semiconductor device package.

3. The semiconductor device according to claim 1, wherein the shield electrode is placed closer to the second electrode than to the first electrode.

4. The semiconductor device according to claim 1, wherein the shield electrode is placed at halfway between the first electrode and the second electrode.

5. The semiconductor device according to claim 1, wherein the third voltage is half the voltage of the first voltage.

6. The semiconductor device according to claim 1, wherein the semiconductor device comprises any of a Gallium Nitride, GaN, or Silicon Carbide, SiC, semiconductor material.

7. The semiconductor device according to claim 1, wherein the semiconductor switching element is a diode.

8. The semiconductor device according to claim 1, wherein the semiconductor switching element further comprises a control electrode for providing a control signal for controlling the semiconductor switching element, wherein the semiconductor switching element is a transistor.

9. A printed circuit board, PCB, comprising:
a first trace adapted to be provided with the first voltage and coupled to the first electrode;
a second trace adapted to be provided with the second voltage and coupled to the second electrode; and
the semiconductor device according to claim 1.

10. The PCB according to claim 9, further comprising a third trace adapted to be provided with the third voltage and coupled to the shield electrode, wherein the shield electrode is placed physically between the first trace and the second trace.

11. A driver for driving a light emitting diode, LED, lighting load, the driver comprising:
the PCB according to claim 9; and
electric components mounted on the PCB as to form a switched mode power supply using the semiconductor switching element as a main power conversion switch.

12. The driver according to claim 11, wherein the driver is formed as any of a buck converter, a boost converter, a buck-boost converter, an LLC converter or a flyback converter.

13. The driver according to claim 11, further comprising a second semiconductor device, wherein the semiconductor device and the second semiconductor device are arranged to operate the switched mode power supply as a synchronous switched mode power supply.

14. The driver according to claim 11, further comprising a second semiconductor device, wherein the semiconductor device and the second semiconductor device are arranged to operate as a half bridge.

15. A luminaire comprising the driver according to claim 11 and the LED lighting load.
